(19) United States
(12) Patent Application Publication
(10) Pub. No.: US 2004/0027197 A1
(43) Pub. Date: Feb. 12, 2004

(54) Power amplifier arrangement

(76) Inventor: Brian Butterfield Howard, Surrey (GB)

Correspondence Address: SQUIRE, SANDERS & DEMPSEY L.L.P., 14TH FLOOR, 8000 TOWERS CRESCENT, TYSONS CORNER, VA, 22182, US

(21) Appl. No.: 10/362,445

(22) PCT Filed: Aug. 3, 2001
(86) PCT No.: PCT/GB01/03512

(30) Foreign Application Priority Data
Aug. 24, 2000 (GB) 0020931.2

(51) Int. Cl. H03G 3/20

(52) U.S. Cl. 330/136

(57) ABSTRACT

A power amplifier arrangement comprising: a power amplifier, said power amplifier having at least a first mode of operation and a second mode of operation, said power amplifier having an input to receive a digitally modulated input signal to be amplified, said modulated input signal being modulated by a constant envelope or a non constant envelope modulation method; and a control signal input, said control signal being arranged to control the mode of operation of the power amplifier; and control signal means for providing said control signal, said control signal means receiving a control signal input indicative of the modulation of said amplifier input signal and providing the control signal in dependence on the modulation of said amplifier input signal.

### FIELD OF THE INVENTION

The present invention relates to a power amplifier arrangement and, in particular but not exclusively, to a power amplifier arrangement for use in a base station in a wireless telecommunications network.

### BACKGROUND TO THE INVENTION

An area covered by a cellular telecommunication network is divided into a plurality of cells. Each of the cells has a base station arranged to transmit signals to and receive signals from mobile stations in the cell associated with the respective base station. Mobile stations will be in active communication with the base station associated with the cell in which the mobile station is located.

The signals which are transmitted between the mobile station and the base station are modulated. Traditionally, the Global System for Mobile communication (GSM) standard has proposed the use of a modulation scheme called Gaussian Mean Shift Keying (GMSK). However, a new modulation scheme has been proposed for use with GSM which is known as enhanced data rate for GSM evolution (EDGE) modulation.

In known base stations, the modulated signal is amplified before it is transmitted. However, EDGE modulation and GMSK modulation generally require the power amplifier to operate at different points in the power amplifier characteristic. In particular, the power amplifier has to be operated in a linear part of the power amplifier for EDGE modulation, that is where the power of the input signal is linearly proportional to the output signal in order to avoid signal distortion. This is because EDGE modulation uses both phase and amplitude information. GMSK is able to operate at a non-linear part of the characteristic of the amplifier. This has the advantage that the power amplifier is operating in its most power efficient region.

It has been proposed to provide base stations which are capable of transmitting signals having EDGE modulation as well as signals having GMSK modulation. So that the power amplifier can be used for both types of modulation, the power amplifier would have to operated in its linear range. However, this would mean that whenever the base station transmitted a signal modulated by the GMSK method, the amplifier would not be operating at its optimum efficiency. In practice, this would mean that the power amplifier would generate more heat, use more power and require a more complex cooling arrangement. Clearly this is undesirable.

### SUMMARY OF THE INVENTION

It is an aim of embodiments of the present invention to address one or more of the problems described above.

According to a first aspect of the present invention there is provided a power amplifier arrangement comprising a power amplifier, said power amplifier having at least a first mode of operation and a second mode of operation, said power amplifier having an input to receive a digitally modulated input signal to be amplified, said modulated input signal being modulated by a constant envelope or a non constant envelope modulation method; and a control signal input, said control signal being arranged to control the mode of operation of the power amplifier; and control signal means for providing said control signal, said control signal means receiving a control signal input indicative of the modulation of said amplifier input signal and providing the control signal in dependence on the modulation of said amplifier input signal.

### BRIEF DESCRIPTION OF DRAWINGS

For a better understanding of the present invention and as to how the same may be carried into effect, reference will now be made by way of example to the accompanying drawings in which:

FIG. 1 shows a typical cell layout of a cellular network;

FIG. 2 schematically shows the transmit part of a base station;

FIG. 3 shows the power characteristics of the power amplifier of FIG. 2;

FIG. 4 shows a power amplifier arrangement embodying the present invention;

FIG. 5 shows the switching circuitry of FIG. 4 in more detail;

FIG. 6 shows the form of the switching signal for the switching circuitry of FIG. 4; and

FIG. 7 shows the power amplifier of FIG. 4 in more detail.

### DETAILED DESCRIPTION OF EMBODIMENTS OF THE PRESENT INVENTION

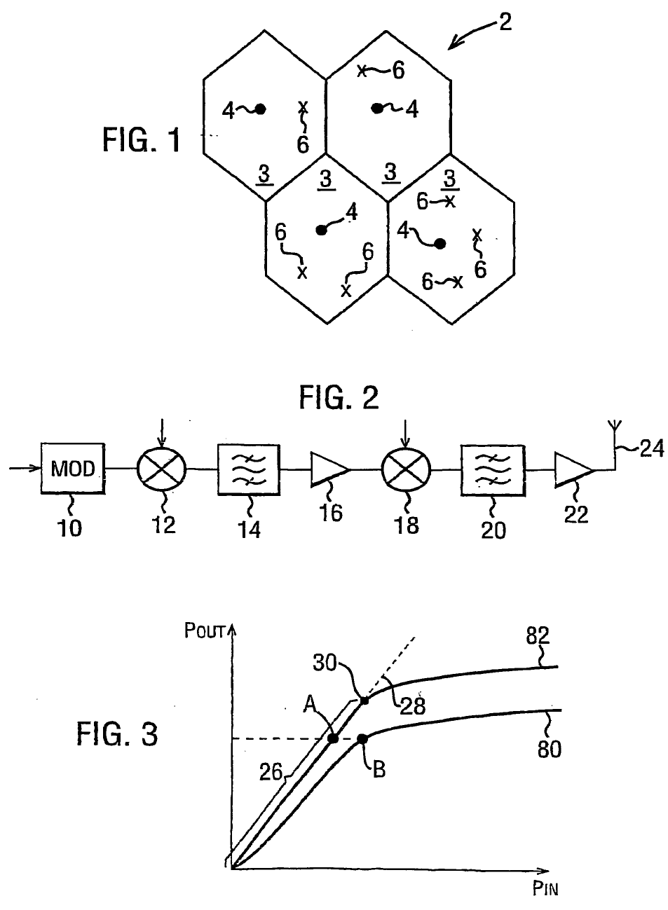

Reference is now made to FIG. 1 which shows part of a cellular telecommunications network in which embodiments of the present invention can be implemented. The area covered by the network is divided into a plurality of cells 3, four of which are shown in FIG. 1. Typically a network will have many more than four cells. Each cell 3 has associated therewith a base transceiver station 4. The base transceiver stations 4 are arranged to communicate with mobile terminals 6 located in the cell associated with a given base station.

Reference is made to FIG. 2 which schematically shows the transmit part of the base station of FIG. 1. The transmit part comprises a modulator 10. The modulator provides a modulated base band signal. The modulator provides digital modulation and will convert the digital modulated signal into an analogue signal. Accordingly, the modulator 10 effective also includes a digital to analogue converter. The modulated analogue signal is output to a first mixer 12. The first mixer 12 mixes the base band signal with a suitable frequency signal so as to provide an intermediate frequency output. The output of the first mixer 12 is filtered by a first band pass filter 14.

The output of the first band pass filter 14 is amplified by an intermediate frequency amplifier 16. The intermediate frequency amplifier 16 is connected to the input of a second mixer 18 which converts the intermediate frequency signal to a radio frequency signal. The output of the mixer 18 is connected to the input of a second band pass filter 20. The output of the second band pass filter 20 is connected to a radio frequency amplifier 22. The amplified signal is then transmitted by an antenna 24.

It should be appreciated that the arrangement of FIG. 2 is schematic and additional filters may be provided. Each of the amplifiers 16 and 22 is shown as a single amplifier. However, each of those amplifiers may be replaced by a chain of amplifiers. In the schematic arrangement shown in FIG. 2, the base band signal is up-converted to the radio frequency signal in two stages. In alternative embodiments of the present invention, a single stage may be used for the up-conversion or more than two can be used.

The bandpass filters 20 are used to filter out any signals which fall outside the bandwidth of interest. These signals can be introduced by, for example, the mixers 12 and 18. The amplifiers 16 and 22 are arranged to amplify the signal so that the signal is transmitted to the mobile station with the required strength. In embodiments of the present invention, the strength with which the base station transmits a signal to a given mobile station may be dependent on the distance between the mobile station and the base station and/or the radio environment.

Reference is made to FIG. 3 which shows a graph of power-out against power-in for the radio frequency amplifier 22 of FIG. 2. The intermediate frequency power amplifier may also have a similar characteristic. As can be seen, the amplifier has a linear region 26. In the linear region, the power of the output signal of the amplifier is linearly dependent on the power of the input signal. Where the modulation applied by the modulator 10 is EDGE modulation, the power amplifier must be operated in the linear region 26. This is because EDGE modulation includes a phase component and an amplitude component. To operate the power amplifier in the non-linear region would cause errors in the signal transmitted by the antenna 24.

Point 28 is known as the P1 point. Effectively, the amplifier operates non-linearly beyond this point. The P1 point is a figure of merit and is defined as the point where there is one dB of compression. Compression is effectively defined as the difference between the power-out if the amplifier continued to operate linearly and the actual power-out. This is the point at which the power amplifier is usually at its most efficient. The linear region 26 extends to a point 30 where the power amplifier begins to saturate. Saturation means that the power of the output signal is no longer linearly related to the power of the input signal.

With GMSK modulation, it is desirable to operate the amplifier in the region of point 28 in order to maximize the efficiency of the power amplifier. In order to ensure that the power amplifier is operating linearly for the EDGE modulation, the power amplifier is typically backed off by around 6 dB. This means that the power amplifier will generally be operated around 6 dB below the P1 point to ensure that the power amplifier operates in its linear region. In other words, for EDGE modulation, the amplifier needs to be operated well within region 26.

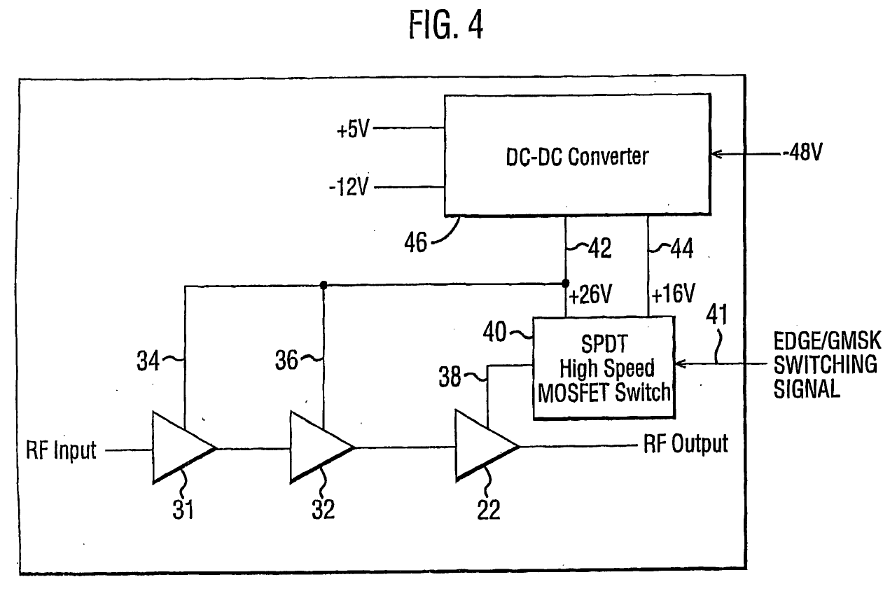

Reference is now made to FIG. 4 which shows a power amplifier arrangement embodying the present invention. This arrangement is arranged to replace radio frequency power amplifier 22 of FIG. 2. In this arrangement, a chain of power amplifiers 31, 32 and 22 are used. It should be appreciated that in an alternative embodiment of the present invention, amplifiers 31 and 32 may be omitted. The three amplifiers are connected in a chain formation. This means that the first amplifier 31 receives a radio frequency input, and provides a amplified radio frequency output which is connected to the second amplifier 32. The second amplifier 32 is arranged to amplify the signal and its output provides the input to the third amplifier 22. The output of the third amplifier 22 is an amplified radio frequency output which is transmitted by the antenna 24. Each of the amplifiers has a respective power supply voltage, 34, 36 and 38. The power supply voltage 38 for the third amplifier 22 is provided by switching circuitry 40.

The switching circuitry 40 has a first voltage input 42 and a second voltage input 44. In this specific example, the first voltage input 42 is at 26 volts whilst the second voltage input 44 is at 18 volts. It should be appreciated that these values are by way of example only and any other suitable voltage values may be used. The switching circuitry 40 also receives a control signal 41. This control signal effectively has one state if GMSK modulation is being used and a second state if EDGE modulation is being used. The switching circuitry 40 is controlled by the control signal. Depending on the type of modulation used, one or other of the two voltage inputs 42 and 44 will be applied as the control signal 38 to the third amplifier 22. In embodiments of the present invention, the 26 volt signal will be applied to the third power amplifier 22 if EDGE modulation is used whilst if GMSK modulation is used, the 18 volt signal will be applied to the third power amplifier.

The first and second amplifiers 31 and 32 both receive the 26 volt signal as the respective control signals 34 and 36.

The two input voltages 42 and 44 to the switching circuitry 40 are generated by a DC to DC converter. The DC to DC converter 46 is conventional and has a positive rail of 5 volts and a negative rail of −12 volts and receives a signal of −48 volts. From this, the DC to DC converter 46 is able to generate the 26 volt signal and the 18 volt signal.

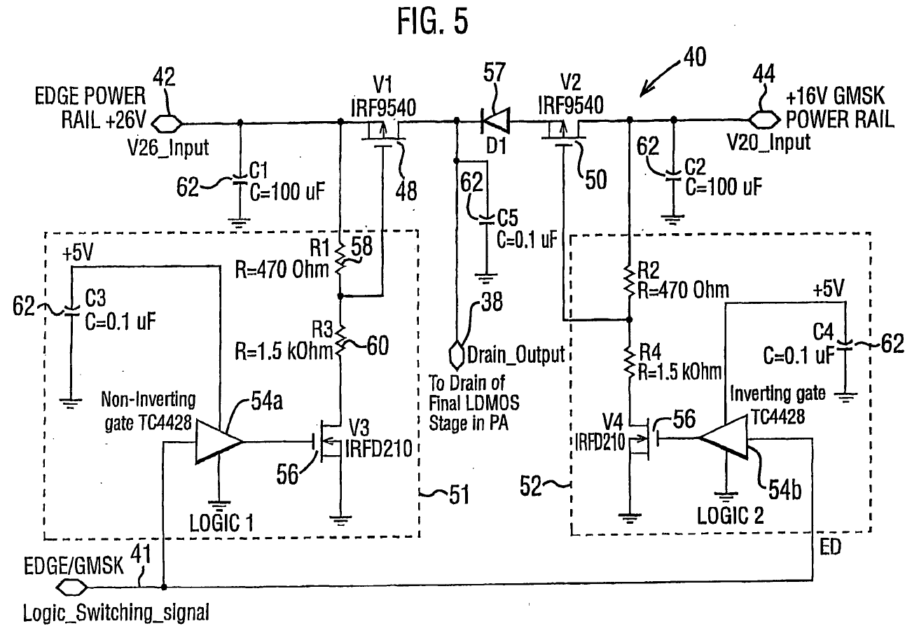

Reference will now be made to FIG. 5 which shows the switching circuitry 40 of FIG. 4 in more detail. The switching circuitry 40 has the input 44 for receiving the 18 volt input and the input 42 for receiving the 26 volt input. These input voltages are applied to the sources of respective first and second switching transistors 48 and 50. The switching transistors 48 and 50 are controlled so that only one of these transistors is switched on at a given time. Whichever of these transistors 48 and 50 is switched on provides the power supply voltage for the third amplifier 22. Thus, if transistor 48 is on, a 26 volt output will be provided by output 38. If, on the other hand, transistor 50 is on, then output 38 will be 16 volts. The output 38 is connected to the drains of the two switching transistors 48 and 50. Each of the first and second switching transistors 48 and 50 has respective control circuitry 51 and 52. The circuitry is the same with the exception of the first gate. The control circuitry 51 for the first switching transistor 48 has a non-inverting gate 54a whilst the circuitry 52 for controlling the second switching transistor 50 has an inverting gate 54b. This means that only one of the two switching transistors 48 and 50 will be on at one time.

Each of the gates 54a and 54b receives the signal from input 41. The gate 54a does not invert the signal whilst the signal is inverted by gate 54b. These gates are each used to control the gate of a control transistor 56. When the respective control transistor 56 is on, the respective switching transistor 48 or 50 is switched off and vice versa.

The gate of the first and second switching transistors 48 and 50 are connected to respective first and second resistors 58 and 60 which are in series with the respective control transistor 56. The gate of the first and second switching transistors 48 and 50 are connected to a node being between respective ones of the first and second resistors 58 and 60. To avoid glitches or the like, various capacitors 62 are, also provided in the circuitry.

A diode 57 is arranged between the first and second switching transistors 48 and 50. This is to avoid the larger voltage causing both of the first and second switching transistors 48 and 50 to be on at the same time.

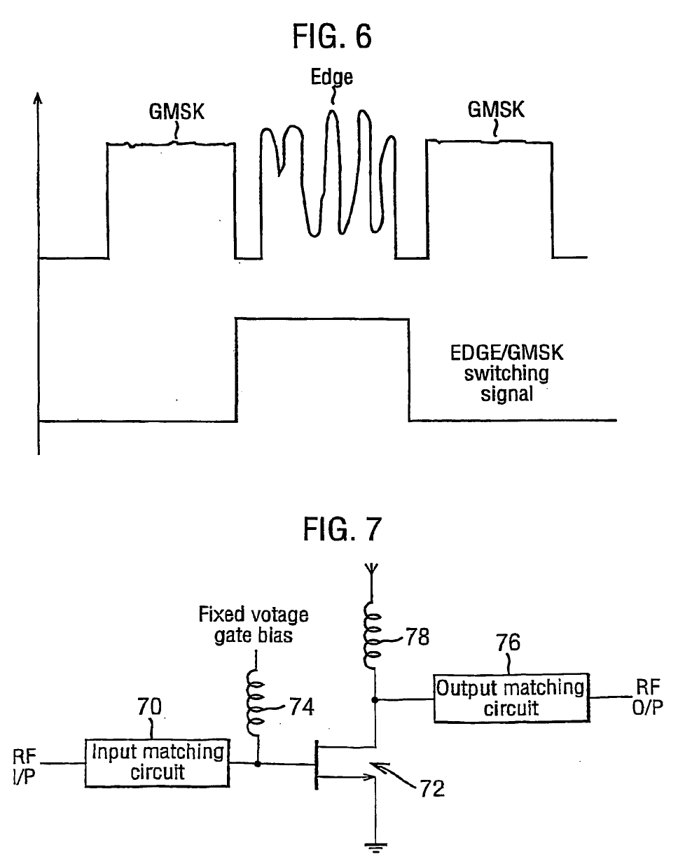

Reference will now be made to FIG. 6 which shows the control signal 41 applied to the switching circuitry. The first part of FIG. 6 shows a typical RF signal which includes some GMSK modulated portions and some EDGE modulated portions. When the input signal to the amplifier has GMSK modulation, the control signal input to the switching circuit is low and when EDGE modulation is used, the input signal is high. It will of course be appreciated that the signal may be high for GMSK and low for EDGE.

Reference is now made to FIG. 7 which shows a block diagram of the structure of the power amplifier 22. The input to the amplifier is input to an input matching circuit 70. The output of the input matching circuit 70 provides the gate input for a transistor 72. The transistor is an RF power transistor having a biased junction to operate in the class AB mode. Also applied to the gate of the transistor 72 is a fixed voltage gate bias which is applied via a RF choke 74. The transistor 72 is arranged so that when there is no input to the amplifier 22, the transistor 72 draws only a very small current. When there, is an input, more power will be drawn by the transistor 72. The transistor 72 is arranged to amplify the signals received from the input matching circuit 70. The amplified signals are output to an output matching circuit 74 which provides the output to the antenna. In series with the transistor 72 is a second RF choke 78.

The RF choke 78 is connected at one end to the output of the switching circuitry 40. The voltage provided by the output of the switching circuitry 40 determines the operating characteristic of the amplifier and in this regard, reference is made to FIG. 3. A second curve is drawn in and is referenced 80. The first curve, referenced 82 is effectively the curve which is used for EDGE modulated input signals where the higher voltage is applied. With the higher voltage applied to the transistor 72, characteristic 82 is obtained. With the lower voltage applied, the characteristic 80 is obtained. As can be seen, point A on the first curve 82 provides the same output power as point B on curve 80. However, point A is well within the linear range of operation of the amplifier. Point B on the second curve 80 is at the more efficient P1 point of operation. Thus, in GMSK mode, the power amplifier operates at its most efficient and thus the amount of heat generated is reduced, the amount of power consumed is reduced and the cooling circuitry is simplified.

It should be appreciated that in some embodiments of the present invention, the occurrence of the GMSK and EDGE modulation parts of the signals may be at random.

Embodiments of the present invention have described application of the invention in the context of a base transceiver station. It should be appreciated that embodiments of the present invention can be used in any other node in a wireless telecommunications system, such as in a mobile station or the like. Embodiments of the present invention may also be used in wired communications systems and indeed may have wider application.

In one modification to embodiments of the present invention, the lower voltage may also be selected for the lower power EDGE time slots. This is because the amount of amplification required is reduced and so sufficient linear amplification may be possible even where the lower voltage is used.

In embodiments of the present invention, it is preferred, but not essential, that both modulation methods be digital modulation methods. Modulation methods other than the two described in embodiments of the present invention can be used. It should be appreciated that more than two modulation methods may be available. Embodiments of the invention may use one modulation method which has a constant envelope modulation (eg GMSK) and one modulation method which has a non constant envelope modulation (eg EDGE).

The switching circuitry described is only one possible switching circuit which can be used in embodiments of the present invention. Depending on the application, optocoupler switches or the like may be used.

In embodiments of the present invention, the last amplifier only is controlled. This is because this is the amplifier which provides the largest effective amplification and thus consumes the most power. However, in alternative embodiments of the present invention, the other power amplifiers can additionally or alternatively be controlled in a similar manner.

The radio frequency transistors may be LDMOS (laterally diffused MOS) FET transistors or any other suitable type of transistor. The transistors can be other types of MOSFETs or based on other types of transistor technology.

1. A power amplifier arrangement comprising:
a power amplifier, said power amplifier having at least a first mode of operation and a second mode of operation, said power amplifier having an input to receive: a digitally modulated input signal to be amplified, said modulated input signal being modulated by a constant envelope or a non constant envelope modulation method; and a control signal input, said control signal being arranged to control the mode of operation of the power amplifier; and
controL signal means for providing said control signal, said control signal means receiving a control signal input indicative of the modulation of said amplifier input signal and providing the control signal in dependence on the modulation of said amplifier input signal.

2. An arrangement as claimed in claim 1, wherein said control signal means is arranged to receive a plurality of inputs, one of which is selected as said control signal in dependence on the control signal input indicative of the modulation of said amplifier input signal.

3. An arrangement as claimed in claim 2, wherein said control signal means comprises switching means.

4. An arrangement as claimed in claim 3, wherein said switching means comprise at least one MOSFET.

5. An arrangement as claimed in claimed in claim 2, 3 or 4, wherein means are provided for providing said plurality of inputs to said control signals.

6. An arrangement as claimed in any of claims 2 to 5, wherein the plurality of inputs to said control means comprise a plurality of different voltages.

7. An arrangement as claimed in claim 6, wherein said providing means are arranged to generate said plurality of voltages.

8. An arrangement as claimed in claim 7, wherein said providing means comprises a DC-DC converter.

9. An arrangement as claimed in 6, 7 or 8, wherein said voltage provided by said providing means is arranged to control a terminal of a transistor of said power amplifier, a level of the voltage altering the operating characteristic of said power amplifier.

10. An arrangement as claimed in any preceding claims, wherein said first mode of operation is a linear mode of operation.

11. An arrangement as claimed in any preceding claim, said second mode of operation is a non linear mode of operation.

12. An arrangement as claimed in any preceding claim, wherein said signal to be amplified is a radio frequency signal.

13. An arrangement as claimed in any preceding claim, wherein the constant envelope modulation method is GMSK.

14. An arrangement as claimed in any preceding claim, wherein the non constant envelope modulation method is EDGE.

15. A wireless communication node comprising an arrangement as claimed in any preceding claim.

16. A node as claimed in claim 15, wherein said node is a base station.
